(19) United States
(12) Patent Application Publication
(10) Pub. No.: US 2024/0250210 A1
(43) Pub. Date: Jul. 25, 2024

(54) LIGHT-EMITTING DEVICE AND MANUFACTURING METHOD THEREOF

(71) Applicant: EPISTAR CORPORATION, Hsinchu (TW)

(72) Inventors: Chia-Che LIAO, Hsinchu (TW); Chih-Hao CHEN, Hsinchu (TW); Wei-Che WU, Hsinchu (TW); Sheng-Hao WU, Hsinchu (TW); Siou-Huei YANG, Hsinchu (TW)

(21) Appl. No.: 18/416,277

(22) Filed: Jan. 18, 2024

(30) Foreign Application Priority Data
Jan. 19, 2023 (TW) 112102563

(51) Int. Cl. H01L 33/16; H01L 33/10

(52) U.S. Cl. CPC H01L 33/16; H01L 33/10

(57) ABSTRACT

A light-emitting device includes a substrate comprising an upper surface, a plurality of side surfaces, and a semiconductor stack located on the upper surface. The substrate includes a hexagonal crystal structure. The plurality of side surfaces includes a first side surface. The first side surface is tilted away from a m-plane of the hexagonal crystal structure, and an acute angle is formed between the first side surface and the m-plane. The first side surface includes a first modified stripe, and the first modified stripe includes a plurality of first modified regions. A pitch is between the adjacent first modified regions, and the pitch is not less than 5 μm. The first side surface comprises a folded structure.

### TECHNICAL FIELD

The application relates to a light-emitting device and methods of making the same, more specifically, to a light-emitting device with an improved production yield and brightness and methods of making the same.

### REFERENCE TO RELATED APPLICATION

This application claims the right of priority based on Taiwan Application Serial No. 112102563, filed on Jan. 19, 2023, and the content of which is hereby incorporated by reference in its entirety.

### DESCRIPTION OF BACKGROUND ART

The light-emitting diodes (LEDs) of the solid-state lighting elements have the characteristics of low power consumption, low heat generation, long operation life, crash proof, small volume, quick response and good opto-electrical property such as light emission with a stable wavelength, so the LEDs have been widely used in household appliances, indicator light of instruments, and opto-electrical products, etc.

A conventional LED basically includes a substrate, an n-type semiconductor layer, an active layer and a p-type semiconductor layer formed on the substrate, and p, n-electrodes respectively formed on the p-type and n-type semiconductor layers. When imposing a certain level of forward voltage to the LED via the electrodes, holes from the p-type semiconductor layer and electrons from the n-type semiconductor layer are combined in the active layer to emit light. While the light-emitting diodes are incorporated into various opto-electrical products whose volumes are getting smaller, a smaller size of the light-emitting diode with qualified opto-electrical characteristics and improved cutting yield is thus desired.

### SUMMARY OF THE APPLICATION

In accordance with an embodiment of the present application, a light-emitting device comprises a substrate comprising an upper surface and a plurality of side surfaces, wherein the plurality of side surfaces comprises a first side surface; and a semiconductor stack located on the upper surface; wherein the substrate comprises a hexagonal crystal structure, the first side surface is tilted away from a m-plane of the hexagonal crystal structure, and an acute angle is formed between the first side surface and the m-plane; wherein the first side surface comprises a first modified stripe, and the first modified stripe comprises a plurality of first modified regions; wherein a pitch is between the adjacent first modified regions, and the pitch is not less than 5 μm; wherein the first side surface comprises a folded structure.

### BRIEF DESCRIPTION OF THE DRAWINGS

The above and other aspects of the application will become better understood with regard to the following detailed description of the preferred but non-limiting embodiment(s). The following description is made with reference to the accompanying drawings. It is noted that, in accordance with the standard practice in the industry, various features are not drawn to scale. In fact, the dimensions of the various features may be arbitrarily increased or reduced for clarity of discussion.

FIG. 1A shows a top view of an epitaxial wafer 100 having a plurality of the light-emitting devices 1 according to an embodiment of the present application.

FIG. 1B shows a cross-sectional view of the epitaxial wafer 100 along line A-A′ in FIG. 1A.

FIG. 1C shows a cross-sectional view of the epitaxial wafer 100 along line B-B′ in FIG. 1A.

FIG. 1D shows a cross-sectional view illustrating one step of manufacturing the light-emitting device according to another embodiment of the present application.

FIG. 2 shows a diagram illustrating a hexagonal crystal structure.

FIG. 3A shows a top view of the light-emitting device 1 according to an embodiment of the present application.

FIG. 3B shows a cross-sectional view of the light-emitting device 1 along line C-C′ in FIG. 3A.

FIGS. 4A-4B show stereoscopic schematic diagrams of the substrate of the light-emitting device 1 according to the embodiments of the present application.

FIGS. 5A-5B show photographs of the substrate of the light-emitting device 1 according to the embodiments of the present application.

FIGS. 6A-6B show top views of the patterned structures 40 of the light-emitting device 1 according to the embodiments of the present application.

FIG. 7 shows luminous intensity distribution curves of the light-emitting device 1 according to the embodiments of the present application.

FIG. 8 shows a light-emitting module including the light-emitting device according to an embodiment of the present application.

FIG. 9 shows a display backlight unit including the light-emitting device according to an embodiment of the present application.

### DETAILED DESCRIPTION OF THE APPLICATION

Exemplary embodiments of the present application will be described in detail with reference to the accompanying drawings hereafter. The following embodiments are given by way of illustration to help those skilled in the art fully understand the spirit of the present application. Hence, it should be noted that the present application is not limited to the embodiments herein and can be realized by various forms. Further, the drawings are not precise scale and components may be exaggerated in view of width, height, length, etc. Herein, the similar or identical reference numerals will denote the similar or identical components throughout the drawings.

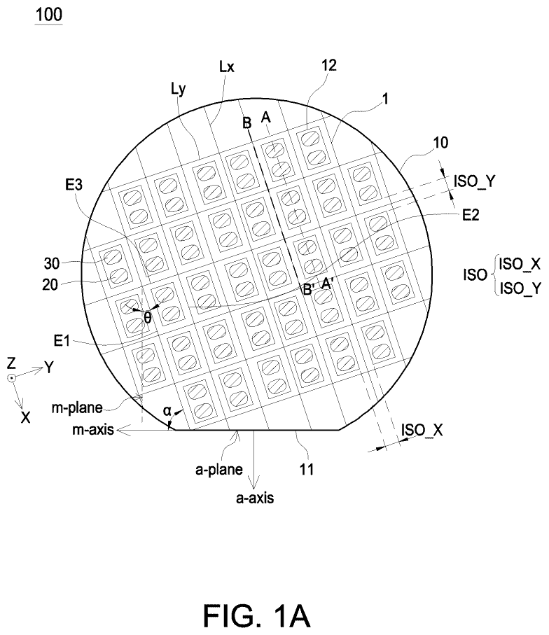

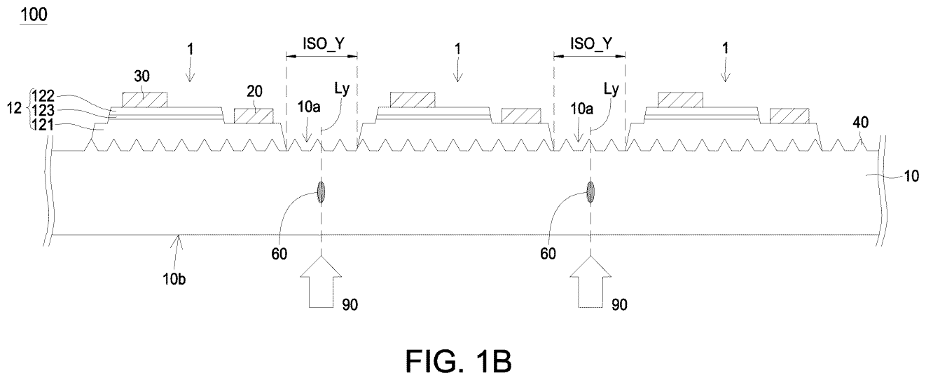

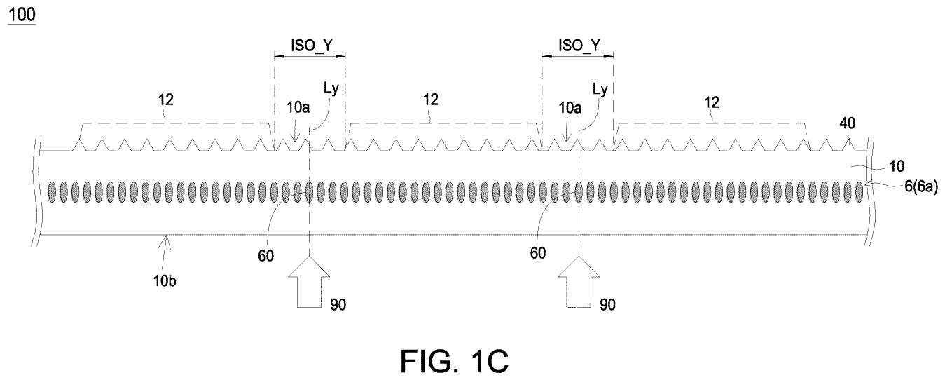

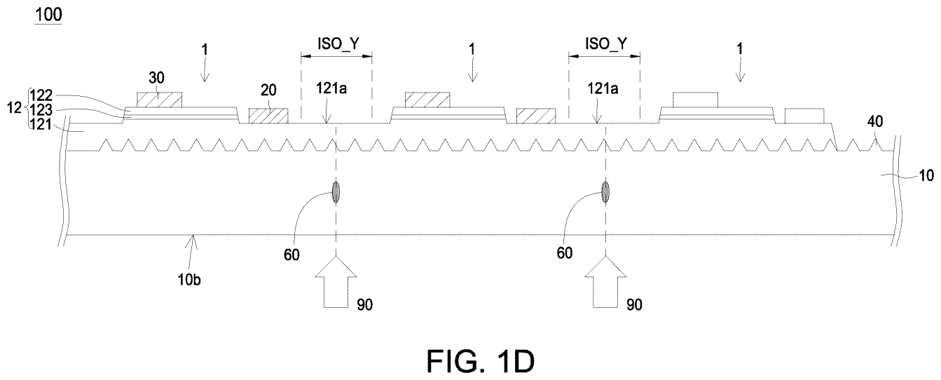

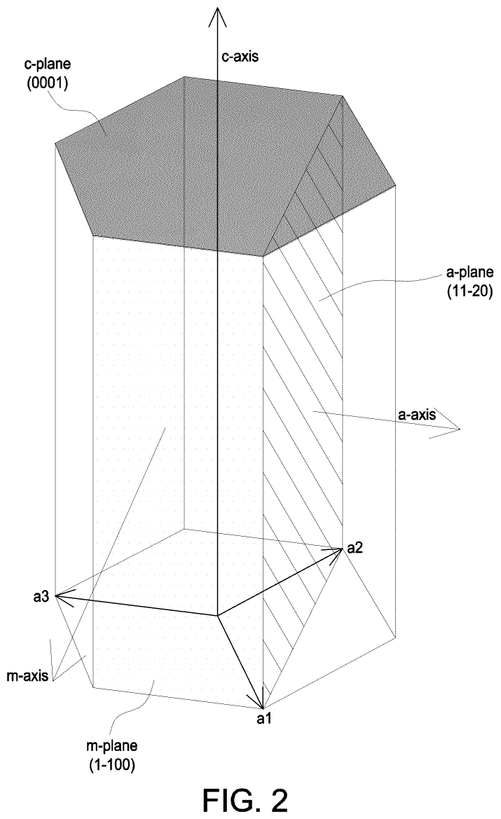

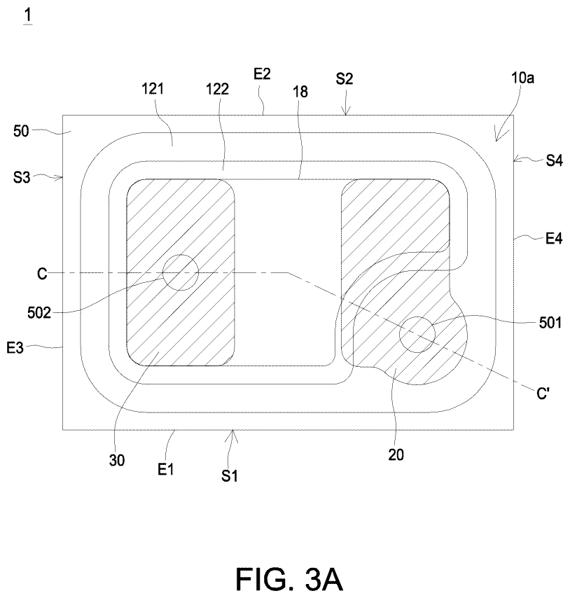

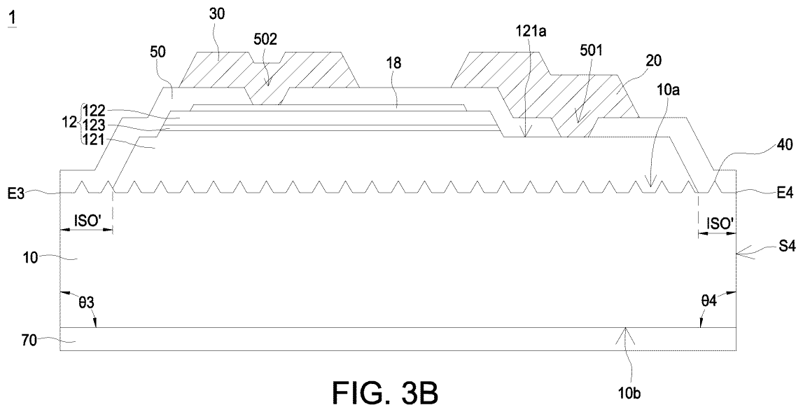

FIG. 1A shows a top view of an epitaxial wafer 100 having a plurality of the light-emitting devices 1 according to an embodiment of the present application. FIG. 1B shows a cross-sectional view of the epitaxial wafer 100 along line A-A′ in FIG. 1A. FIG. 1C shows a cross-sectional view of the epitaxial wafer 100 along line B-B′ in FIG. 1A. FIG. 2 shows a diagram illustrating a hexagonal crystal structure. FIG. 3A shows a top view of the light-emitting device 1 cut from the epitaxial wafer 100 according to an embodiment of the present application. FIG. 3B shows a cross-sectional view of the light-emitting device 1 along line C-C′ in FIG. 3A. The manufacturing method of the light-emitting device 1 is described below. It should be noted that, to simplify the drawings, FIG. 1A to FIG. 1C do not illustrate all the elements of the light-emitting device 1. People having ordinary skill in the art can refer to the details described below in the present embodiment, such as FIG. 3A, FIG. 3B, and the relevant paragraphs, to understand the specific structure of the light-emitting device 1.

As shown in FIGS. 1A and 1B, an epitaxial wafer 100 includes a substrate 10 and a plurality of semiconductor stacks 12 formed on an upper surface 10a of the substrate 10. After a subsequent cutting process is completed, each of the plurality of semiconductor stacks 12 and the substrate 10 form a light-emitting device 1. The substrate can be a growth substrate including a hexagonal crystal structure, such as sapphire. As shown in FIG. 2, a hexagonal crystal structure has a c-plane (0001), an a-plane (11-20), and an m-plane (1-100). The orthogonal directions of the above-mentioned planes are the c-axis, the a-axis (a1-axis, a2-axis, a3-axis) and the m-axis, respectively. Herein, the m-plane (1-100) and other crystalline planes which are equivalent to m-plane (the m-plane family {1-100}, not shown in the diagram) are collectively referred as the m-plane. Such description also applies to the c-plane and the a-plane. In this embodiment, the upper surface 10a of the substrate is composed of the c-plane. The Z-axis direction shown in FIG. 1A is the c-axis direction of the hexagonal crystal structure, and the XY-plane is substantially parallel with the c-plane. It is noteworthy here that considering the manufacturing ability and epitaxial quality, “c-plane” is defined by a plane having an off angle with the c-plane in a range between +1 degree, including c-plane itself. In one embodiment, the off angle is 0.2 degrees. In one embodiment, as shown in FIG. 1A, the substrate 10 includes an edge 11 from a top view. The edge 11 is essentially a straight line. A side surface of the substrate 10 where the edge 11 located is composed of the a-plane and is also used as an orientation flat to define the crystal direction of the substrate 10. However, the present application is not limited to this embodiment herein, and those skilled in the art can realize a notch can also be used to define the crystal direction of the substrate 10 besides the edge 11. In the following, for convenience of description, the substrate of the epitaxial wafer 100 and the substrate of the light-emitting device 1 cut from the epitaxial wafer 100 are all denoted as the same name and label.

In one embodiment, as shown in FIG. 1B, the substrate 10 can be a patterned substrate, that is, the upper surface 10a of the substrate 10 comprises a plurality of patterned structures 40. In one embodiment, the light emitted from the semiconductor stack 12 can be refracted, reflected or scattered by the patterned structures 40 of the substrate 10 to enhance the light extraction efficiency of the light-emitting device. In addition, the patterned structures 40 reduce or suppress the dislocation due to the lattice mismatch between the substrate 10 and the semiconductor stack 12 to improve the epitaxy quality of the semiconductor stack 12. The patterned structures and the substrate 10 may comprise the same material or different materials, wherein the patterned structures comprise different materials, such as silicon oxide, silicon nitride, or silicon oxynitride.

As shown in FIGS. 1A, 1B, 1C, 3A and 3B, the manufacturing method of the epitaxial wafer 100 is described below. First, the semiconductor stack 12 is formed on the upper surface 10a of the substrate 10. As shown in FIG. 1B, the semiconductor stack 12 includes a first semiconductor layer 121, an active layer 123 and a second semiconductor layer 122 sequentially formed on the substrate 10. Then, portions of the active layer 123 and the second semiconductor layer 122 are removed to expose an upper surface 121a of the first semiconductor layer 121.

In an embodiment of the present application, the semiconductor stack 12 can be formed on the substrate 10 by metal-organic chemical vapor deposition (MOCVD), molecular beam epitaxy (MBE), hydride vapor phase epitaxy (HVPE), or ion plating, such as sputtering or evaporation.

In one embodiment, before forming the semiconductor stack 12, a buffer structure (not shown) can be formed on the substrate 10. The buffer structure can reduce the dislocation due to the lattice mismatch between the substrate 10 and the semiconductor stack 12 to improve the epitaxy quality. The material of the buffer structure includes GaN, AlGaN or AlN. In one embodiment, the buffer structure includes a plurality of sub-layers (not shown). The sub-layers include the same material or different materials. In one embodiment, the buffer structure includes two sub-layers. The growth method of the first sub-layer is different from that of the second sub-layer, for example, the growth method of the first sub-layer is sputtering, and the growth method of the second sub-layer is MOCVD. In one embodiment, the buffer structure further includes a third sub-layer. The growth method of the third sub-layers is MOCVD, and the growth temperature of the second sub-layer is higher than or lower than that of the third sub-layer. In one embodiment, the first, second and third sub-layers include the same material, such as AlN.

In one embodiment, the first semiconductor layer 121 and the second semiconductor layer 122, such as a cladding layer or a confinement layer, have different conductivity types, electrical properties, polarities, or doping elements for providing electrons or holes. For example, the first semiconductor layer 121 is an n-type semiconductor, and the second semiconductor layer 122 is a p-type semiconductor. The active layer 123 is formed between the first semiconductor layer 121 and the second semiconductor layer 122. The electrons and holes combine in the active layer 123 under a current driving to convert electric energy into light energy to emit a light. The wavelength of the light emitted from the light-emitting device 1 or the semiconductor stack 12 is adjusted by changing the physical property and chemical composition of one or more layers in the semiconductor stack 12.

The material of the semiconductor stack 12 includes a group III-V semiconductor material, such as AlₓIn_{y}Ga_{(1-x-y)}N or AlₓIn_{y}Ga_{(1-x-y)}P, wherein 0≤x, y≤1; (x+y)≤1. According to the material of the active layer, when the material of the semiconductor stack 12 is AlInGaP series material, red light having a wavelength between 610 nm and 650 nm or yellow light having a wavelength between 550 nm and 570 nm can be emitted. When the material of the semiconductor stack 12 is InGaN series material, blue or deep blue light having a wavelength between 400 nm and 490 nm or green light having a wavelength between 490 nm and 550 nm can be emitted. When the material of the semiconductor stack 12 is AlGaN series material, UV light having a wavelength between 250 nm and 400 nm can be emitted. The active layer 123 can be a single heterostructure (SH), a double heterostructure (DH), a double-side double heterostructure (DDH), or a multi-quantum well structure (MQW). The material of the active layer 123 can be i-type, p-type, or n-type semiconductor.

As shown in FIGS. 1A-1C, portions of the semiconductor stack 12 are removed by dry etching or wet etching to expose the upper surface 10a of the substrate 10 to form a plurality of cutting lanes ISO, including multiple first cutting lanes ISO_X which are mutually parallel with each other and multiple second cutting lanes ISO_Y which are mutually parallel with each other. The location of each set-apart semiconductor stack 12 is thus defined by the first cutting lanes ISO_X and the second cutting lanes ISO_Y.

It should be noted that, there is no semiconductor stack 12 on the upper surface 10a of the substrate in the first cutting lanes ISO_X since FIG. 1C is a cross-sectional view at line B-B′ segment along one of the first cutting lanes ISO_X. However, in order to mark the corresponding position of the second cutting lanes ISO_Y, the semiconductor stack 12 adjacent to line B-B′ in side view is represented by a dotted line in FIG. 1C. In one embodiment, the first cutting lanes ISO_X and the second cutting lanes ISO_Y are perpendicular to each other. In an embodiment of the present application, the first cutting lanes ISO_X and the second cutting lanes ISO_Y are not parallel with the a-axis and m-axis, respectively. In an embodiment of the present application, the technology of forming the first cutting lanes ISO_X and the second cutting lanes ISO_Y by removing portions of the semiconductor stack 12 could be the traditional technology such as, but not limited to, laser method, diamond cutting method. In addition, the order of forming the cutting lanes ISO_X and ISO_Y and forming the upper surface 121a of the first semiconductor layer can be adjusted. In some embodiments, instead of removing portions of the semiconductor stack 12 to expose the upper surface 10a of the substrate 10 to form a plurality of cutting lanes ISO, a portion of the semiconductor stack 12 is removed by dry etching or wet etching, and another portion of the semiconductor stack 12, for example, a portion of the buffer structure, is retained. Thus, the upper surface of the retained buffer structure is exposed to form the cutting lanes ISO.

Then, a transparent conductive layer 18 is formed on the second semiconductor layer 122. The specific structure of the transparent conductive layer 18 is shown in FIGS. 3A and 3B. The transparent conductive layer 18 can spread current and form a low-resistance contact, such as ohmic contact. The transmittance of the transparent conductive layer 18 is high to the light emitted from the active layer 123, for example, larger than 80%. The material of the transparent conductive layer 18 may be a metal or transparent conductive material. The metal material includes gold (Au) or nickel gold, and the transparent conductive material includes graphene, indium tin oxide (ITO), aluminum zinc oxide (AZO), gallium zinc oxide (GZO), zinc oxide (ZnO) or indium zinc oxide (IZO).

Then, an insulating structure 50 is formed on the semiconductor stack 12, and includes a first opening 501 and a second opening 502. The structure of the insulating structure 50 is shown in FIGS. 3A and 3B. The first opening 501 exposes the first semiconductor layer 121, and the second opening 502 exposes the transparent conductive layer 18. In one embodiment, the insulating structure 50 covers the upper surface 10a of the substrate in the first cutting lanes ISO_X and the second cutting lanes ISO_Y. The insulating structure 50 includes an insulated material, such as silicon oxide, silicon nitride, silicon oxynitride, niobium oxide, hafnium oxide, titanium oxide, magnesium fluoride, or aluminum oxide. The insulating structure 50 can be one layer or multiple layers composed of different insulated materials. In one embodiment, the insulating structure 50 comprising sub-layers of insulated materials with different refractive indices alternately stacked can selectively reflect light of a specific range of wavelength and/or a specific range of incident angles by means of alternatives of materials with different refractive indices and thickness of sub-layers. Thus, the insulating structure 50 can be a reflective structure. In one embodiment, the insulating structure 50 is, for example, a Distributed Bragg Reflector (DBR) structure. For example, the insulating structure 50 has a reflectivity of more than 60% with respect to the dominant wavelength and/or peak wavelength of the light-emitting device 1.

As shown in FIGS. 3A and 3B, a first electrode 20 and a second electrode 30 are formed on the insulating structure 50, wherein the first electrode 20 covers the first opening 501 and is electrically connected to the first semiconductor layer 121, and the second electrode 30 covers the second opening 502 and is electrically connected to the second semiconductor layer 122. The first electrode 20 and the second electrode 30 comprise a metal material, such as chromium (Cr), aluminum (Al), indium (In), tin (Sn), platinum (Pt), nickel (Ni), gold (Au), titanium (Ti), tungsten (W), silver (Ag), or a laminate or an alloy of the above materials. In one embodiment, after forming a light emitting device 1, the light emitting device 1 is in the form of flip chip to bond the first electrode 20 and the second electrode 30 to a circuit carrier board (not shown), and is connected to external electronic components or an external power supply through a circuit of the circuit carrier board. The first electrode 20 and the second electrode 30 serve as current paths for the external power supply to the first semiconductor layer 121 and the second semiconductor layer 122.

In another embodiment (not shown), the light-emitting device 1 may further include other electrode layers, such as metal contact electrode layers or current spreading electrode layers, located between the first electrode 20 or the second electrode 30 and the semiconductor stack 12 to meet the requirements of current spreading.

In another embodiment, as shown in FIG. 3B, the substrate 10 further comprises a lower surface 10b and a reflection structure 70 is formed adjacent to the lower surface 10b. The reflection structure 70 includes a metal reflection structure or an insulating reflection structure, wherein the insulating reflection structure including sub-layers of insulated materials with different refractive indices alternately stacked can selectively reflect light of a specific range of wavelength and/or a specific range of incident angles by means of alternatives of materials with different refractive indices and thickness of sub-layers. The reflection structure 70 is, for example, a Distributed Bragg Reflector (DBR) structure or an omni-directional reflector. After the light emitting device 1 is formed, the light emitted from the semiconductor stack 12 can then emit from a plurality of the side surfaces of the substrate 10 by the reflection of the reflection structure 70. In another embodiment, there is no reflection structure 70 formed adjacent to the lower surface 10b, the light emitted from the semiconductor stack 12 can then emit from the lower surface 10b of substrate 10 and the plurality of the side surfaces of the substrate 10.

The epitaxial wafer 100 is formed according to the above embodiments. As shown in FIG. 1A, the plurality of semiconductor stacks 12 is arranged in arrays on the upper surface 10a of the substrate, wherein each of the plurality of semiconductor stacks 12 corresponds to each light emitting device 1 formed after the subsequent cutting process is completed. From a top view, each of the plurality of semiconductor stacks 12 includes a first edge E1 parallel with the X-axis direction and a third edge E3 parallel with the Y-axis direction, respectively. In an embodiment of the present application, the X-axis direction and the Y-axis direction are both set not to be parallel with the a-axis and the m-axis of the hexagonal crystal structure.

As shown in FIGS. 1B and 1C, a cutting process is performed after the epitaxial wafer 100 is formed. In one embodiment, the thickness of the substrate 10 is reduced to a specific thickness before performing the cutting process or forming the reflection structure 70 adjacent to the lower surface 10b of the substrate. The cutting process includes performing a laser irradiation step. A laser 90 is used to irradiate the epitaxial wafer 100, for example, irradiate from the back of the epitaxial wafer 100 along the cutting lanes ISO_X and ISO_Y and focus inside the substrate 10. A focus point inside the substrate 10 is affected by the laser energy and forms a plurality of modified regions 60 inside the substrate 10. According to the trajectory of the laser 90 moving along the first cutting lanes ISO_X and the second cutting lanes ISO_Y, a modified stripe 6(6a) in the X-axis direction and a modified stripe in the Y-axis direction (Y-axis direction is not shown in FIGS. 1B and 1C) are formed, respectively. The modified stripe 6(6a) comprises the plurality of modified regions 60. Cracks are generated inside the substrate 10 due to the influence of the laser energy in a plurality of modified regions 60, and the cracks extend to the upper and lower cross-sectional surfaces to form crack surfaces. The occurrence of the crack surfaces can generally be regarded as a pre-crack phenomenon, which is caused by a stress generated from the modified regions 60 inside the substrate, such as the volume expansion stress and thermal stress. A first cutting line Lx and a second cutting line Ly from a top view as shown in FIG. 1A are formed after the crack surfaces are generated.

After the occurrence of crack surfaces, the cutting process further includes performing a substrate cutting step. For example, an external force can be applied to the epitaxial wafer 100 to cause the substrate 10 to break along the crack surfaces to form a light-emitting device 1. In the light-emitting device 1, the above-mentioned modified stripe and modified regions can be observed on the crack surfaces of the substrate 10, i.e., the side surfaces of the substrate 10 after cutting. A pitch is the distance between the adjacent modified regions 60, and can be controlled by tuning laser parameters of the laser equipment, such as speed and frequency. In one embodiment, the pulse oscillation frequency of the laser 90 is, for example, 10,000 Hz to 300,000 Hz, and the moving speed of the adsorptive stage is, for example, 100 mm/sec to 1,000 mm/sec.

The first cutting line Lx is substantially parallel with the first cutting lanes ISO_X, and the second cutting line Ly is substantially parallel with the second cutting lanes ISO_Y. Therefore, the first cutting line Lx and the second cutting line Ly are both not parallel with the a-axis and the m-axis of the hexagonal crystal structure. Specifically, an acute angle α is formed between the first cutting line Lx and the m-axis. The m-plane and the XY-plane are virtually intersected by a virtual intersection line which is substantially parallel with the a-axis shown in FIG. 1A, and an acute angle θ is formed between the virtual intersection line and the first cutting line Lx, wherein θ=90°−α. In one embodiment, the acute angle θ is in a range between 5 degrees and 25 degrees.

In one embodiment, the laser irradiation can be implemented in the X-axis direction first, and then implemented in the Y-axis direction. In another embodiment, the order of irradiation in the X-axis and the Y-axis directions can be reversed. In one embodiment, multiple laser irradiation steps can be performed along the same cutting lane. For example, a first laser irradiation is performed in a certain direction and focused on a first depth in the substrate 10. Then, a second laser irradiation is performed in the above-mentioned direction and focused on a second depth in the substrate 10 that is different from the first depth. Thus, multiple modified stripes in the above-mentioned direction can be formed on the same side surface of the substrate 10. The modified stripes are substantially parallel with each other, and there exists a distance between the modified stripes in Z-axis. In another embodiment, multiple focus points with different depths on the same side surface can be generated by the design of the optical mechanism of the laser equipment and laser parameters. Therefore, multiple modified stripes can be formed on the same side surface in the substrate 10 with one-time laser irradiation. In one embodiment, the depths of laser irradiation focused in the respective X-axis and the respective Y-axis directions may be the same or different. When the depths of laser irradiation focused in the X-axis and the Y-axis directions are the same, the modified stripe on the side surface in the X-axis direction and that on the side surface in the Y-axis directions of the substrate 10 after cutting are connected to each other. When the depths of laser irradiation focused in the X-axis and the Y-axis directions are not the same, the modified stripe on the side surface in the X-axis direction and that on the side surface in the Y-axis direction of the substrate 10 after cutting are not connected to each other. In one embodiment, the times of performing laser irradiation in the X-axis and the Y-axis directions may be the same or different. In an exemplary embodiment, the times of performing laser irradiation in the X-axis and the Y-axis directions are different. For example, a first laser irradiation is performed in the X-axis direction and focused on a first depth in the substrate 10, and then a second laser irradiation is performed in the Y-axis direction and focused on a second depth. Subsequently, a third laser irradiation is performed in the X-axis direction and focused on a third depth. The first depth, second depth, and third depth are different from each other. In another embodiment, the first depth is different from the third depth, and the second depth is same with the first depth or the third depth. Therefore, there are different amounts of modified stripes on the side surfaces in different directions.

FIG. 1D shows a cross-sectional view illustrating one step of manufacturing the light-emitting device according to another embodiment and the difference from FIG. 1B is the formation method of the plurality of cutting lanes ISO. As shown in FIG. 1D, the plurality of cutting lanes ISO is not defined by removing portions of the semiconductor stack 12 to expose the upper surface 10a of the substrate, but by a default area of the upper surface 121a of the first semiconductor layer. The subsequent laser irradiation step and substrate cutting step are the same as the above-mentioned embodiments, and the difference is that the first semiconductor layer 121 is cut simultaneously in the substrate cutting step.

FIG. 3A shows a top view of the light-emitting device 1 cut from the epitaxial wafer 100 according to an embodiment of the manufacturing method of the light-emitting device. FIG. 3B shows a cross-sectional view of the light-emitting device 1 along line C-C′ in FIG. 3A. The light-emitting device 1 includes a substrate 10, a semiconductor stack 12 located on the upper surface 10a of the substrate, a transparent conductive layer 18 located on the second semiconductor layer 122, an insulating structure 50 covering the semiconductor stack 12 and the transparent conductive layer 18, and a first electrode 20 and a second electrode 30 located on the insulating structure 50. The upper surface 10a of the substrate includes an isolation region ISO′ formed after the epitaxial wafer 100 is cut along the plurality of cutting lanes ISO and located around the semiconductor stack 12. The insulating structure 50 includes the first opening 501 to uncover the first semiconductor layer 121 and the second opening 502 to uncover the transparent conductive layer 18. The first electrode 20 covers the first opening 501 and is electrically connected to the first semiconductor layer 121, and the second electrode 30 covers the second opening 502 and is electrically connected to the second semiconductor layer 122. In one embodiment, the light-emitting device 1 further includes the reflection structure 70 formed adjacent to the lower surface 10b of the substrate.

As shown in FIGS. 3A and 3B, the substrate 10 comprises a plurality of side surfaces, wherein the plurality of side surfaces includes a first side surface S1, a second side surface S2, a third side surface S3, and a fourth side surface S4. From a top view, the upper surface 10a of the substrate includes a first edge E1, a second edge E2, a third edge E3, and a fourth edge E4, wherein the first edge E1 is opposite to the second edge E2 and the third edge E3 is opposite to the fourth edge E4. The upper surface 10a connects the first, second, third and fourth side surfaces by the first, second, third and fourth edges, respectively. The side surfaces are also the crack surfaces of the substrate 10 formed during the substrate cutting step of the epitaxial wafer 100. The first edge E1 and the second edge E2 are formed during the crack surfaces extend to the first cutting line Lx on the upper surface of the substrate 10. The third edge E3 and the fourth edge E4 are formed during the crack surfaces extend to the second cutting line Ly on the upper surface of the substrate 10. As mentioned above, there is an acute angle θ between the first cutting line Lx and the virtual intersection line of the m-plane and the XY-plane. Therefore, the corresponding first edge E1 and second edge E2 also form an acute angle θ with the above-mentioned virtual intersection line. Besides, the crack surfaces corresponding to the first cutting line Lx, that is, the first side surface S1 and the second side surface S2, are also tilted away from the m-plane with an angle, i.e., the acute angle θ mentioned above. More specifically, the acute angle θ is formed between a projection of the first side surface S1 or the second side surface S2 on a c-plane of the hexagonal crystal structure and a projection of the m-plane on the c-plane. In one embodiment, the acute angle θ is in a range between 5 degrees and 25 degrees. In one embodiment, a morphology of the upper surface 10a of the substrate can be observed after the upper surface 10a is wet etched to realize the above-mentioned angle and the relative relationship between the hexagonal crystal structure and the plurality of side surfaces.

In traditional laser cutting technology, the direction of the cutting lanes is set to be parallel with the a-axis or the m-axis. It is because the r-plane (1-102) of the hexagonal crystal structure is a plane that is easy to release stress, the crack surfaces generated by the plurality of modified regions in the cutting lanes parallel with the a-axis does not crack along the m-plane, but crack along the r-plane, also called as an oblique crack of the substrate. Since the r-plane is tilted away from the c-plane, the side surfaces of the substrate formed thereof can also be tilted. It not only affects a luminous intensity distribution of the light-emitting device, but also makes the light-emitting device fail as the above-mentioned oblique crack of the substrate extends to the semiconductor stack. According to this embodiment of the light-emitting device and its manufacturing method thereof, multiple first cutting lanes ISO_X and multiple second cutting lanes ISO_Y are tilted away from the a-axis and the m-axis respectively to make the crack surfaces not easy to crack along the r-plane. Specifically, the first side surface S1 and the second side surface S2 are both designed to be tilted away from the m-plane, and the third side surface S3 and the fourth side surface S4 are both designed to be tilted away from the a-plane. Therefore, in one embodiment, an included angle between the lower surface 10b of the substrate and any one of the plurality of side surfaces S1 to S4, such as θ3 and θ4 shown in FIG. 3B, can be controlled between 84 and 96 degrees to improve the oblique crack of the substrate during conventional laser cutting process.

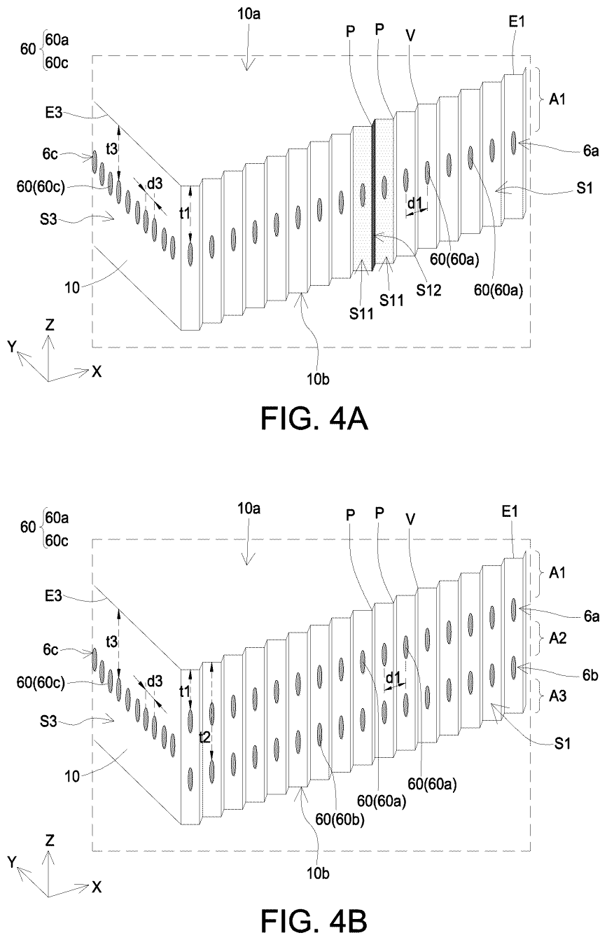

FIGS. 4A and 4B show stereoscopic schematic diagrams of the substrate of the light-emitting device 1 according to the embodiments of the present application. In one embodiment, as shown in FIG. 4A, the first side surface S1 of the substrate 10 comprises a first modified stripe 6a and a folded structure, wherein the first modified stripe 6a comprises a plurality of first modified regions 60a arranged along the X-axis direction. The folded structure comprises a plurality of ridge portions P and a plurality of valley portions V. A pitch d1 is the distance between the adjacent first modified regions 60a, and can be set within a specific range by tuning laser parameters of the cutting process. In one embodiment, the formation cause of the folded structure is described in details as below. During the cutting process, the crack surfaces formed by the plurality of modified regions inside the substrate tends to crack along the crystal plane of the substrate itself. In this embodiment, first cutting line Lx and the first side surface S1 are both set to be tilted away from the m-plane, and the pitch d1 is set to be within in a specific range. Multiple first crack surfaces S11 caused by each of the plurality of first modified regions 60(60a) tend to crack along the m-plane, and those first crack surfaces S11 are roughly parallel with the same direction. Since the X-axis direction which the plurality of first modified regions 60a arranged along is tilted away from the m-plane, the adjacent first crack surfaces S11 are not easy to connect to each other directly and multiple second crack surfaces S12 between two adjacent first crack surfaces S11 are thus formed in a different direction. The plurality of first modified regions 60(60a) repeatedly generates discontinuities as what happened to the adjacent first crack surfaces S11 mentioned above, and finally a folded structure is formed as shown in FIG. 4A on the crack surfaces of the substrate, i.e., the first side surface S1. The folded structure comprises a plurality of ridge portions P and a plurality of valley portions V, and the plurality of ridge portions P extends from the first modified stripe 6a towards the upper surface 10a or the lower surface 10b of the substrate. The folded structure on the plurality of side surfaces of the substrate is beneficial to light emission from the light-emitting device 1, thereby improving the brightness of the light-emitting device 1. When the plurality of modified regions is arranged densely, for example, when the pitch d1 is less than 5 μm, the crack surfaces generated by the adjacent modified regions can be continuously connected to each other, the folded structure is thus not easy to be formed. That means most areas on the plurality of side surfaces of the substrate are flat surfaces except the areas of modified stripes, for example, over 80% of the areas other than the areas of modified stripes are flat surfaces. In one embodiment, the thickness of the substrate 10 is between 40 μm and 800 μm, and the pitch d1 is not less than 5 μm. In another embodiment, the pitch d1 is between 8 μm and 20 μm. In another embodiment, the thickness of the substrate 10 is between 60 μm and 250 μm.

In one embodiment, portions of or all the ridge portions P extend towards the upper surface 10a of the substrate and make the folded structure form a zig-zag shape on the first edge E1 as shown in FIG. 4A. Microscopically, the zig-zag shape on the first edge E1 includes sections which are not parallel with the X-axis direction. Macroscopically, the first edge E1 extends along the X-axis direction viewing from the overall of the light-emitting device 1. The first edge E1 forms an acute angle θ with the virtual intersection line of the m-plane and the XY-plane. In another embodiment, when the plurality of ridge portions P extends from the first modified stripe 6a towards the upper surface 10a of the substrate, the height of the plurality of ridge portions P (i.e., the height of the plurality of ridge portions P relative to the XZ-plane in FIG. 4A) gradually decreases. That makes the first edge E1 form a shape unlike zig-zag or form an unobvious zig-zag shape. The first side surface S1 comprises a first zone A1 located between the upper surface 10a and the first modified stripe 6a, and the folded structure is located in the first zone A1. In another embodiment, the folded structure located in the first zone A1 is more obvious than the folded structure located between the first modified stripe 6a and the lower surface 10b of the substrate. Therefore, the number (or the density) of the ridge portions P in the first zone A1 is higher than the number (or the density) of the ridge portions P between the first modified stripe 6a and the lower surface 10b of the substrate on the first side surface S1. The arrangement of the plurality of ridge portions P may be regular or irregular. In another embodiment, the plurality of ridge portions P may extend continuously between the upper surface 10a and the lower surface 10b of the substrate. In another embodiment, the plurality of ridge portions P disconnects from the first modified regions 60a and extends towards the upper surface 10a and the lower surface 10b of the substrate, respectively.

Although the folded structure on the third side surface S3 is not shown in FIG. 4A, the folded structure can also be formed on the third side surface S3 as the folded structure formed on the first side surface S1 in the above embodiment. In one embodiment, the third side surface S3 comprises a third modified stripe 6c, wherein the third modified stripe 6c comprises a plurality of third modified regions 60c arranged along the Y-axis direction and a pitch d3 is the distance between the adjacent third modified regions 60c. In one embodiment, the pitch d3 can be set within a specific range by tuning laser parameters of the cutting process, for example, the pitch d3 is set between 8 μm and 20 μm. Those skilled in the art can understand the present embodiment from the content disclosed in this study, since the second cutting line Ly and the third side surface S3 are both set to be tilted away from the a-plane, the crack surfaces caused by each of the plurality of third modified regions 60(60c) tend to crack along the a-plane when the pitch d3 is set within the above-mentioned range. Since the Y-axis direction which the plurality of third modified regions 60(60c) arranged along is tilted away from the a-plane, the adjacent crack surfaces caused by each of the plurality of third modified regions 60(60c) are not easy to connect to each other directly and a folded structure is thus formed on the third side surface S3, which is the same as the way the folded structure formed on the first side surface S1. In one embodiment, the folded structure on the third side surface S3 can form a zig-zag shape on the third edge E3 (not shown), wherein the specific details and embodiments of the plurality of ridge portions P of the folded structure on the third side surface S3 can be referred to the aforementioned plurality of ridge portions P of the folded structure on the first side surface S1 and will not be described again here. In another embodiment, the pitch d1 and the pitch d3 can be set to be different, so that different degrees of folded structures can be obtained on the first side surface S1 and the third side surface S3 or the folded structure can only be formed in one of the X-axis and the Y-axis directions.

FIG. 4B shows a stereoscopic schematic diagram of the substrate of the light-emitting device 1 according to another embodiment, and the difference from FIG. 4A is that the first side surface S1 further comprises a second modified stripe 6b located between the first modified stripe 6a and the lower surface 10b of the substrate. The second modified stripe 6b is substantially parallel with the first modified stripe 6a. The first side surface S1 comprises a second zone A2 located between the first modified stripe 6a and the second modified stripe 6b and a third zone A3 located between the second modified stripe 6b and the lower surface 10b of the substrate. In one embodiment, the folded structure is located in the second zone A2. In another embodiment, the folded structure is located in the second zone A2 and in the third zone A3. As shown in FIGS. 4A and 4B, a pitch t1 is a distance between the first modified stripe 6a and the upper surface 10a of the substrate, a pitch t2 is a distance between the second modified stripe 6b and the upper surface 10a of the substrate, and a pitch t3 is a distance between the third modified stripe 6c and the upper surface 10a of the substrate. The pitch t3 can be the same as or different from any of the pitches t1 and t2. In one embodiment where t3=t1 or t3=t2, the third modified stripe 6c is connected to the first modified stripe 6a or the second modified stripe 6b. In one embodiment where t3 is not equal to t1 nor t2, the third modified stripe 6c and the first modified stripe 6a or the second modified stripe 6b may not be connected.

Although neither the second side surface S2 nor the fourth side surface S4 is shown in FIGS. 4A and 4B, those skilled in the art can understand that the cutting process is performed in the same manner in the X-axis direction or in the Y-axis direction of the epitaxial wafer 100. Therefore, the second side surface S2 and the first side surface S1 of the substrate 10 include the same structure, and the fourth side surface S4 and the third side surface S3 include the same structure. The relevant details will not be described again here.

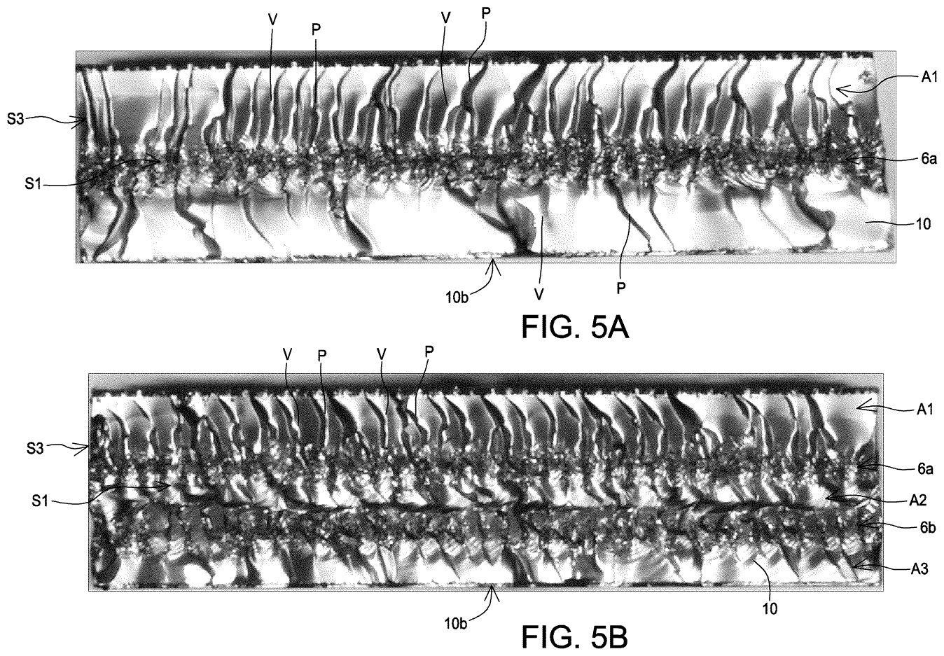

FIGS. 5A-5B show photographs of the substrate of the light-emitting device 1 according to the embodiments of the present application, wherein FIG. 5A corresponds to the embodiment of FIG. 4A and FIG. 5B corresponds to the embodiment of FIG. 4B, respectively. FIG. 5A shows that the folded structure located in the first zone A1 is more obvious than that located between the first modified stripe 6a and the lower surface 10b of the substrate. The number (or the density) of the ridge portions P in the first zone A1 is higher than the number (or the density) of the ridge portions P between the first modified stripe 6a and the lower surface 10b of the substrate. FIG. 5B shows that the folded structure is located in the first zone A1, the second zone A2 and the third zone A3, and the folded structure located in the first zone A1 is more obvious than the folded structure located in the second zone A2 and the third zone A3. Therefore, the number (or the density) of the ridge portions P in the first zone A1 is higher than the number (or the density) of the ridge portions P in the second zone A2 and the third zone A3 on the first side surface S1.

In order to measure the steepness of the undulation of the side surface of the substrate, a root mean square slope RΔq of the side surface can be derived. The root mean square slope is one of the parameters of surface roughness, which can express the slope of the undulating relief on a surface. In one embodiment, the first zone A1 has a first root mean square slope RΔq_1, the first modified stripe 6a has a second root mean square slope RΔq_2, and the second zone A2 has a third root mean square slope RΔq_3, and the third zone A3 has a fourth root mean square slope RΔq_4, wherein RΔq_1 (RΔq_3 or RΔq_4)>0.5×RΔq_2. In another embodiment, RΔq_1 (RΔq_3 or RΔq_4)>0.75×RΔq_2. In another embodiment, RΔq_1 (RΔq_3 or RΔq_4)>RΔq_2. Table 1 shows the root mean square slopes measured in various zones of the first side surface of the substrate of the light emitting device 1 according to an embodiment of the present application and a comparative example, wherein the unit of the root mean slope is degree. In the light-emitting device 1 of the embodiment, the first side surface S1 of the substrate 10 includes the structure as shown in FIG. 4B and FIG. 5B. The included angle θ between the first side surface S1 and the m-plane is designed to be 17 degrees. A pitch between the adjacent first modified regions 60a of the first modified stripe 6a and a pitch between the adjacent second modified regions 60b of the second modified stripe 6b are both set to be 11 μm. The only difference between the light-emitting device of the comparative example and the light-emitting device 1 of the embodiment is that the included angle θ between the first side surface S1 and the m-plane is designed to be 0 degree, that is, the first side surface S1 is substantially parallel with the m-plane.

TABLE 1

| Zone | Comparative example | Example 1 |
|---|---|---|
| First zone A1 | 3.144 | 32.141 |
| first modified stripe 6a | 24.409 | 27.495 |
| Second zone A2 | 15.297 | 25.009 |
| second modified | 29.497 | 33.998 |
| stripe 6b | | |
| Third zone A3 | 16.777 | 21.297 |

Generally speaking, in traditional laser cutting technology, the plurality of modified regions formed at the focus point inside the substrate can form a rough surface. For example, the modified stripes have the highest root mean square slopes in the comparative example as shown in Table 1. However, in the zones other than the modified stripes, the root mean square slope is lower than that of the modified stripes, and a relatively flat surface is formed in the first zone A1. In contrast, in the light-emitting device 1 of this embodiment, a root mean square slope of the modified stripes is comparable to that in the comparative example. In the zones other than the modified stripes, the root mean square slope is higher than that of the modified stripes due to the aforementioned folded structure in this embodiment. That means a structure located in the zones other than the modified stripes which is beneficial to light emission can be derived.

Table 2 below shows the brightness comparison of the light-emitting devices according to different embodiments of the present application and the light-emitting devices of the comparative examples. The light-emitting devices of each embodiment below all include a structure like that shown in FIG. 3B. A reflection structure 70 is set to be adjacent to the lower surface 10b of the substrate and an insulating structure 50 is set on the surface of the semiconductor stack 12. The reflection structure 70 and the insulating structure 50 each comprises a Distributed Bragg Reflector (DBR). The light generated from the semiconductor stack 12 emits through the plurality of side surfaces of the substrate via the reflection of the reflection structure 70 and the insulating structure 50. The pitch between the adjacent modified regions 60 is set to be 11 μm. The difference between different embodiments lies in the included angle θ between the first side surface S1 of the substrate and the m-plane, the amounts of modified stripes and the thickness of the substrate.

In each set of experiments, the difference of the comparative examples from the embodiments is that the included angle θ between the first side surface S1 of the substrate and the m-plane is 0 degree, that is, the first side surface S1 in the comparative examples is substantially parallel with the m-plane. The brightness difference is measured with the brightness of the comparative examples as reference values. In the first set of experiments, Examples 1-1 to 1-3 have a brightness improvement of more than 1% compared to Comparative Example 1. In the second set of experiments, Examples 2-1 to 2-3 have a brightness improvement between 0.5% and 3.6% compared to Comparative Example 2, wherein, the light-emitting device with an included angle θ of 17 degrees has the highest brightness. This also validates the results shown in Table 1. According to the embodiments of the present application, a structure conducive to light emission can be formed in the zones other than the modified stripes on the plurality of side surfaces by the folded structure to improve the overall brightness of the light-emitting device.

TABLE 2

| | Light-emitting devices | | | |
|---|---|---|---|---|
| | | Amounts | | |
| | | of | | |
| | | modified | | |
| | Substrate | stripes | Included | Brightness |
| | thickness | (in X-axis; | angle θ | difference |
| | (μm) | in Y-axis) | (degree) | (%) |
| Comparative | 100 | 2; 1 | 0 | Reference |
| example 1 | | | | value |
| Example 1-1 | 100 | 2; 1 | 17 | 1.19 |
| Example 1-2 | 100 | 2; 1 | 13 | 1.12 |
| Example 1-3 | 100 | 2; 1 | 9 | 1.05 |
| Comparative | 125 | 2; 2 | 0 | Reference |
| example 2 | | | | value |
| Example 2-1 | 125 | 2; 2 | 17 | 3.6 |
| Example 2-2 | 125 | 2; 2 | 13 | 1.04 |
| Example 2-3 | 125 | 2; 2 | 9 | 0.5 |

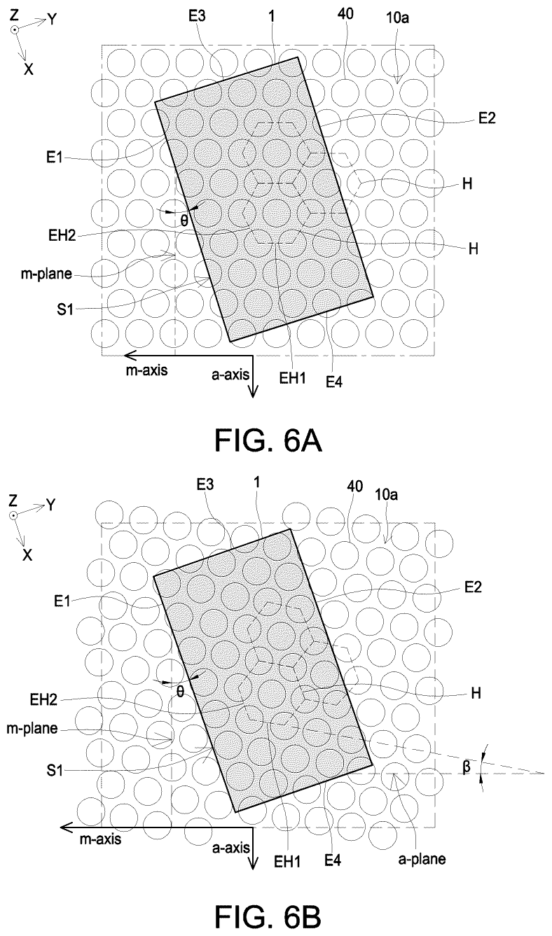

FIGS. 6A and 6B show schematic diagrams of the arrangement and layout of the patterned structures 40 of the substrate of the light-emitting device according to the embodiments of the present application. The gray area in FIGS. 6A and 6B shows the light-emitting device 1 and the four edges E1 to E4 of the upper surface 10a of the substrate, which can also be regarded as a partially enlarged view of the epitaxial wafer 100 in FIG. 1A. It should be noted that FIGS. 6A and 6B are for illustrating the relative relationship among the patterned structure 40, the light-emitting device 1 and the hexagonal crystal structure, but not to reflect the actual scale. In one embodiment, a plurality of patterned structures 40 is provided on the upper surface 10a of the substrate, and the plurality of patterned structures 40 forms a regularly arranged pattern. For example, referring to FIGS. 6A and 6B, a plurality of patterned structures 40 may form a regular hexagonal repeating pattern H. Specifically, in one embodiment, six patterned structures 40 are arranged at six vertices of the regular hexagonal pattern H, and one patterned structure 40 is arranged at the center of the regular hexagonal pattern H. The shape of the patterned structures 40 may be a cone, a hemisphere, a polygonal pyramid, a cylinder, a polygonal prism, etc. According to the aforementioned embodiment, the first side surface S1 of the substrate of light-emitting device 1 is tilted away from the m-plane and forms an acute angle θ, and one side EH1 of the regular hexagonal pattern H is substantially perpendicular to the a-axis (that is, EH1 is parallel with the a-plane).

In another embodiment, referring to FIG. 6B, the difference from FIG. 6A is that one side EH1 of the regular hexagonal pattern H is not perpendicular to the a-axis, and EH1 rotates clockwise by an acute angle β relative to the a-plane. In one embodiment, the angle β is not less than 5 degrees. In another embodiment, the angle β is less than or equal to the angle θ. When the difference of the angle β and the angle θ is lower, the extension direction of the first edge E1 and the second edge E2 can be more consistent with the arrangement direction of the patterned structures 40, that is, the extension direction of the first edge E1 and the second edge E2 is more consistent with the direction of one of any side of the regular hexagonal pattern H. In one embodiment, the insulating structure 50 locates on the patterned structures 40 in the isolation region ISO′ (as shown in FIGS. 3A and 3B) after a light-emitting device 1 is cut and formed from the epitaxial wafer 100. When the extending direction of the first edge E1 and the second edge E2 is more consistent with the arrangement direction of the patterned structures 40, a neat outer contour can be formed from a top view on the first edge E1 and the second edge E2 to avoid irregular outer contours such as burrs after the light-emitting device 1 is cut from the epitaxial wafer 100. In another embodiment, the angle β can also be appropriately altered so that the extension direction of the third edge E3 and the fourth edge E4 is close to or consistent with the arrangement direction of the patterned structures 40. In one embodiment, a morphology of the upper surface 10a of the substrate and the patterned structures 40 can be observed after the upper surface 10a is wet etched to realize the above-mentioned angle β and the relative relationship between the hexagonal crystal structure and the plurality of side surfaces. It should be noted that the pattern formed by the plurality of patterned structures 40 is not limited to a regular hexagon, and other shapes such as a regular rectangle are also applicable.

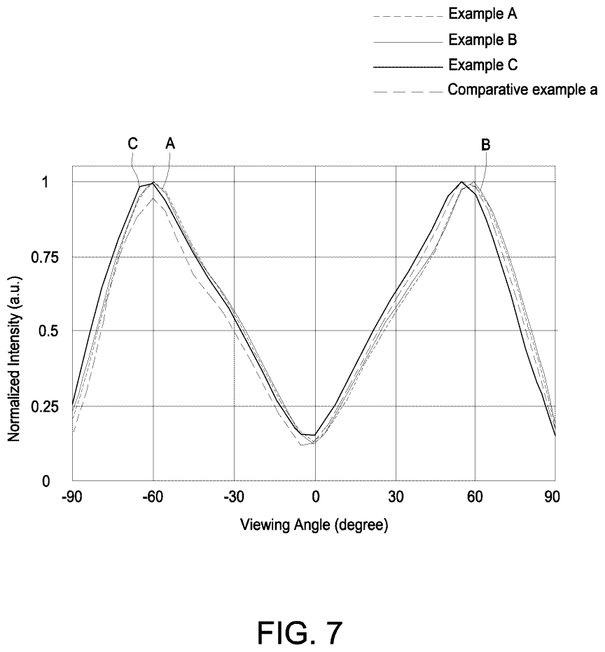

FIG. 7 shows the optical measurement results of the light-emitting devices according to the embodiment of the present application and the comparative example. FIG. 7 shows a Cartesian coordinate luminous intensity distribution curves measured along the Y-axis in a far-field region, wherein each light-emitting device includes a structure like that shown in FIG. 3B. A reflection structure 70 is set to be adjacent to the lower surface 10b of the substrate and an insulating structure 50 is set on the surface of the semiconductor stack 12. The reflection structure 70 and the insulating structure 50 each comprises a Distributed Bragg Reflector (DBR). The light generated from the semiconductor stack 12 emits through the plurality of side surfaces of the substrate via the reflection of the reflection structure 70 and the insulating structure 50. Other specific details and embodiments can be referred to the Comparative example a and Examples A to C in Table 3 below respectively.

The symmetry of the luminous intensity distribution of the light-emitting device, that is, the symmetry of the luminous intensity distribution of the light emitted through the first side surface S1 and the second side surface S2 can be observed in FIG. 7. The brightness peak difference in Table 3 refers to the difference between the maximum luminous intensity at an angle of 0 degree to 90 degrees and the maximum luminous intensity at an angle of 0 degree to −90 degrees of the luminous intensity distribution curve. The symmetry of the luminous intensity distribution is better when the brightness peak difference is smaller. The brightness trough offset angle in Table 3 refers to the difference between the angle of a lowest luminous intensity and 0 degree. The smaller the offset angle is, the better the symmetry of the luminous intensity distribution is. According to the light-emitting device according to the embodiment of the present application, the brightness peak difference can be controlled to be less than 5%, and more preferably, less than 2.5%. In addition, the angle of the brightness trough can be controlled within −7.5 degrees to +7.5 degrees, and more preferably, be controlled within −5 degrees to +5 degrees. It means that the symmetry of the luminous intensity distribution can be enhanced by improving the oblique crack of the substrate so that the side surfaces of the substrate and the lower surface of the substrate are nearly vertical according to the light-emitting device 1 and manufacturing method thereof in the present embodiment.

TABLE 3

| | Light-emitting devices | | | | |
|---|---|---|---|---|---|
| | | Amounts | | Bright- | Bright- |
| | | of | | ness | ness |
| | | modified | | peak | trough |
| | Substrate | stripes | Included | differ- | offset |
| | thickness | (in X-axis; | angle θ | ence | angle |
| | (μm) | in Y-axis) | (degree) | (%) | (degree) |
| Comparative | 100 | 2; 2 | 0 | 5.61 | 5 |
| example a | | | | | |
| Example A | 100 | 2; 2 | 17 | 1.59 | 0 |
| Example B | 100 | 2; 2 | 13 | 0.11 | 0 |
| Example C | 100 | 2; 2 | 9 | 0.63 | 0 |

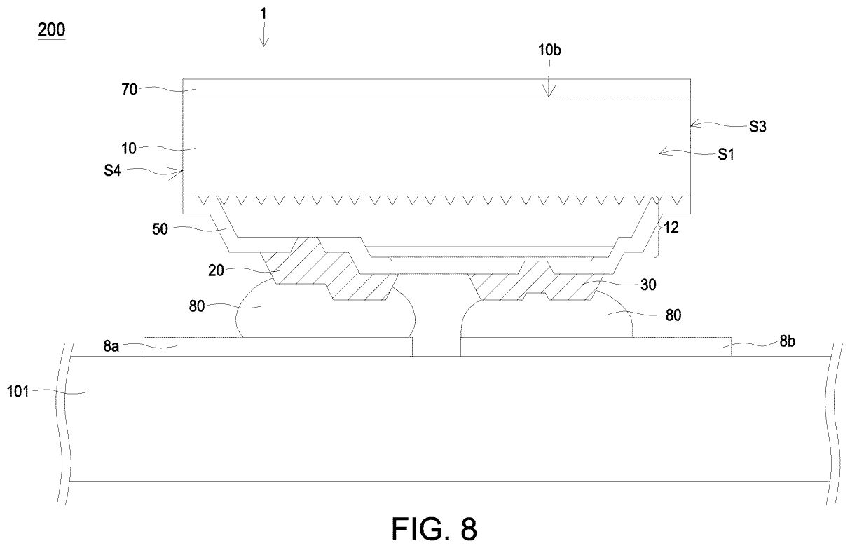

FIG. 8 shows a light-emitting module 200, which includes the light-emitting device 1 according to any embodiment of the present application. The light-emitting module 200 includes a carrier board 101, and there are a circuit (not shown) and circuit bonding pads 8a and 8b set on the carrier board 101. The light-emitting device 1 is mounted in the form of flip chip to bond the first electrode pad 20 and second electrode pad 30 respectively to the circuit bonding pads 8a and 8b via the conductive bonding layer 80. In one embodiment, bonding methods include but are not limited to adhesive bonding, eutectic bonding and solder bonding, wherein the conductive bonding layer 80 can be conductive adhesive, eutectic metal layer or metal solder. In another embodiment, the light-emitting device 1 may not include the reflective structure 70, so that the light generated by the semiconductor stack 12 is mainly emitted through the lower surface 10b and the side surfaces S1 to S4 of the substrate. In one embodiment, the light-emitting module 200 may further include a transparent adhesive material (not shown) located on the carrier board 101 to cover the light-emitting device 1. The transparent adhesive material includes silicone, epoxy, acrylate, or combination thereof.

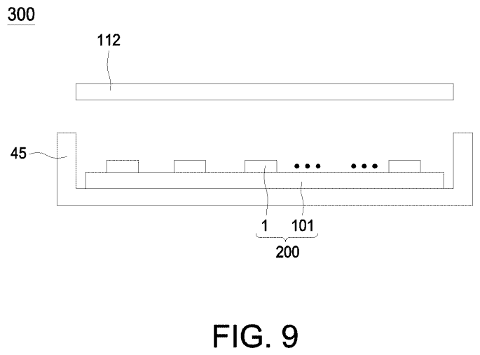

FIG. 9 shows a cross-sectional view of a display backlight unit 300. The display backlight unit 300 includes the light-emitting device 1 of any of the aforementioned embodiments. The display backlight unit 300 includes a housing 45 and the housing 45 accommodates the light-emitting module 200 as shown in FIG. 8. An optical film 112 is disposed above the light-emitting module 200, wherein the optical film 112 is, for example, a light diffuser. In this embodiment, the display backlight unit 300 is a direct backlight unit. The light-emitting module 200 includes a carrier board 101, and the light-emitting devices 1 according to any embodiment of the present application are mounted and arranged on the carrier board 101. In another embodiment (not shown), the light-emitting module 200 includes a carrier board 101 and a plurality of light-emitting device packages mounted and arranged on the upper surface of the carrier board 101. The plurality of light-emitting device packages encloses the light-emitting devices of any of the aforementioned embodiments and is mounted on the upper surface of the carrier board 101 in the form of flip chip. Generally speaking, if the luminous intensity distribution of the light-emitting device is asymmetrical, the overall light source brightness of the display backlight unit including such light-emitting device can be uneven. Since the light-emitting device according to the embodiment of the present application has higher brightness and symmetrical luminous intensity distribution, the display backlight unit 300 can improve the above problems and enhance the image quality of the display.

While the present disclosure has been described by way of example and in terms of the preferred embodiment (s), it is to be understood that the present disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light-emitting device, comprising:
a substrate, comprising an upper surface and a plurality of side surfaces, wherein the plurality of side surfaces comprises a first side surface; and
a semiconductor stack located on the upper surface;
wherein the substrate comprises a hexagonal crystal structure comprising a m-plane, the first side surface is tilted away from the m-plane of the hexagonal crystal structure, and an acute angle is formed between the first side surface and the m-plane;
wherein the first side surface comprises a first modified stripe, and the first modified stripe comprises a plurality of first modified regions;
wherein a pitch is between the adjacent first modified regions, and the pitch is not less than 5 μm;
wherein the first side surface comprises a folded structure.

2. The light-emitting device according to claim 1, wherein from a top view, the upper surface comprises an edge and connects the first side surface by the edge, and the folded structure forms a zig-zag shape on the edge.

3. The light-emitting device according to claim 1, wherein the first side surface comprises a first zone located between the upper surface and the first modified stripe, and the folded structure is located in the first zone.

4. The light-emitting device according to claim 1, wherein the folded structure comprises a plurality of ridge portions and a plurality of valley portions, the plurality of ridge portions extends from the first modified stripe towards the upper surface.

5. The light-emitting device according to claim 3, wherein the first zone comprises a first root mean square slope RΔq_1, the first modified stripe comprises a second root mean square slope RΔq_2, and wherein RΔq_1>0.5×RΔq_2.

6. The light-emitting device according to claim 5, wherein RΔq_1>RΔq_2.

7. The light-emitting device according to claim 1, wherein the first side surface comprises a second modified stripe, and the second modified stripe comprises a plurality of second modified regions, and the first side surface comprises a second zone located between the first modified stripe and the second modified stripe.

8. The light-emitting device according to claim 7, wherein the folded structure is located in the second zone, the second zone comprises a third root mean square slope RΔq_3 and the first modified stripe comprises a second root mean square slope RΔq_2, wherein RΔq_3>0.5×RΔq_2.

9. The light-emitting device according to claim 1, wherein the substrate further comprises a lower surface, and an angle formed between the lower surface and the first side surface is in a range of between 84 degrees and 96 degrees.

10. The light-emitting device according to claim 9, wherein the first side surface comprises a third zone located between the second modified stripe and the lower surface, and the folded structure is located in the third zone.

11. The light-emitting device according to claim 9, further comprising a first reflection structure adjacent to the lower surface.

12. The light-emitting device according to claim 1, wherein the light-emitting device comprises a first maximum luminous intensity at an angle of 0 degree to 90 degrees of a luminous intensity distribution curve measured in a far-field region, and comprises a second maximum luminous intensity at an angle of 0 degree to −90 degrees of the luminous intensity distribution curve, and the difference between the first maximum luminous intensity and the second maximum luminous intensity is lower than 5%.

13. The light-emitting device according to claim 11, wherein the light-emitting device comprises a lowest luminous intensity at an angle of −7.5 degrees to +7.5 degrees of the luminous intensity distribution curve.

14. The light-emitting device according to claim 1, further comprising a second reflection structure located on a surface of the semiconductor stack.

15. The light-emitting device according to claim 1, wherein the acute angle is formed between a projection of the first side surface on a c-plane of the hexagonal crystal structure and a projection of the m-plane on the c-plane, and the acute angle is in a range between 5 degrees and 25 degrees.

16. The light-emitting device according to claim 1, wherein the plurality of side surfaces comprises a second side surface, the second side surface is opposite to the first side surface, and an acute angle formed between a projection of the second side surface on a c-plane of the hexagonal crystal structure and a projection of the m-plane on the c-plane is in a range between 5 degrees and 25 degrees.

17. The light-emitting device according to claim 1, wherein the plurality of side surfaces comprises a third side surface, the third side surface comprises a third modified stripe, and the third modified stripe comprises a plurality of third modified regions, wherein the third side surface comprises a folded structure.

18. The light-emitting device according to claim 17, wherein the third modified stripe does not connect to the first modified stripe.

19. The light-emitting device according to claim 1, wherein the pitch of the adjacent first modified regions is in a range between 8 μm and 20 μm.
